(19) United States
(12) Patent Application Publication
(10) Pub. No.: US 2014/0007814 A1
(43) Pub. Date: Jan. 9, 2014

(54) EVAPORATION DEVICE FOR A VACCUM DEPOSITION APPARATUS AND VACUUM DEPOSITION APPARATUS COMPRISING SUCH AN EVAPORATION DEVICE

(71) Applicant: RIBER, Bezons Cedex (FR)

(72) Inventors: Jerome VILLETTE, Le Plessis Robinson (FR); Jean-Louis GUYAUX, Chilly Mazarin (FR); David ESTEVE, Bougival (FR)

(21) Appl. No.: 13/934,534

(22) Filed: Jul. 3, 2013

(30) Foreign Application Priority Data
Jul. 4, 2012 (FR) 12 56424

(51) Int. Cl. C23C 14/24

(52) U.S. Cl. CPC C23C 14/243
USPC 118/727

(57) ABSTRACT

An evaporation device for a vacuum deposition apparatus includes a crucible to contain a material to be evaporated and a bottom, a body and an opening, and a heating element surrounding at least partially the crucible body, the evaporation device being placed inside a chamber with pressure <10⁻³ mbar. The device also includes at least one thermal shield between the crucible body and the heating element, the thermal shield including at least one element movable with respect to the crucible and designed so the heat received by the body of the crucible at a considered point of this body conforms, at a given instant of time, to a non-constant function of the distance between the considered point and the bottom of the crucible, this function being adjustable as regards at least one degree of movability of the first element of the thermal shield with respect to the crucible.

The invention relates to an evaporation device that can be used in a vacuum deposition apparatus including a crucible and a thermal shield arranged at the periphery of the crucible.

The evaporation devices are used in the industry to equip vacuum deposition apparatuses serving in depositing layers—sometimes very thin—of material on substrates of various sizes.

It is known that an evaporation device for a vacuum deposition apparatus includes:
a crucible intended to contain a material to be evaporated, comprising a bottom, a body and an opening, and
heating means surrounding at least partially the body of the crucible.

It is also known that such an evaporation device is intended to be placed inside a vacuum chamber of the vacuum deposition apparatus in which the pressure is lower than 10⁻³ mbar.

In these conditions of pressure, the heating of the crucible body by the heating means is made essentially through radiation, the vacuum inside the vacuum chamber reducing the convection heat exchanges.

According to the prior art, the whole crucible, as well as the material to be evaporated contained therein, are heated to a high temperature. This heating of the crucible is thus uniform and leads to heating both the part of the material to be evaporated that is close to the crucible opening and the part of the material to be evaporated that is close to the crucible bottom.

The inventors have analyzed that, during the materiel evaporation required for making the deposition, a flow of steam escapes from the crucible opening, coming essentially from the free surface of the material to be evaporated close to the crucible opening. The steam pressure that defines the capacity to generate this flow is governed by the temperature at this free surface.

Consequently, the part of the material to be evaporated that is close to the crucible opening is progressively consumed during the evaporation.

However, the part of the material to be evaporated that is located at the middle and at the bottom of the crucible is heated for a longer duration than the part of the material to be evaporated that is located close to the opening.

Hence, the different parts of the crucible body are heated in a uniform way and are subjected to the same temperature of evaporation for durations that are sometimes long. The material under the free surface, which does not contribute predominantly to the evaporation, undergoes at least the same temperature than the evaporating free surface. The continuous exposition of the material to the flow of heat favors the degradation of the material to be evaporated. In particular, at the end of the evaporation, the material located in the lower part of the crucible will have undergone a temperature of evaporation for a longer time than the material placed in the upper part.

In order to remedy the above-mentioned drawback, the invention proposes an evaporation device for a vacuum deposition apparatus including at least one thermal shield interposed between the crucible body and the heating means, the thermal shield comprising at least one first element that is movable with respect to the crucible and that is designed in such a manner that the quantity of heat received by the body of the crucible at a considered point of this body is conform, at given instant of time, to a non-constant function of the distance between the considered point and the bottom of the crucible, this function being adjustable as regards at least one degree of movability of the first element of the thermal shield with respect to the crucible.

The present invention thus proposes an evaporation device that allows heating in a non-uniform manner the different parts of the crucible body and making the quantity of heat received by these different parts vary over time.

The heating of the parts of the material to be evaporated contained in the crucible that do not contribute directly to the useful flow of steam is then limited and controlled.

Indeed, the evaporation device according to the invention allows for example heating locally the material to be evaporated at its free surface close to the crucible opening without exposing the remaining of the material to be evaporated to a strong heat that could finally deteriorate its physicochemical properties.

Therefore, by inserting the thermal shield between the crucible body and the heating means, a part of the material to be evaporated contained in the crucible is preserved from a part of the flow of heat radiated by the heating means toward the crucible body. The thermal shield transmits only a part of the radiated flow of heat to the crucible body and reflects the other part. The thermal shield thus operates as a mirror for the heat radiated by the heating means.

This thermal shield comprises at least one first element, movable with respect to the crucible, which allows uncovering a given part of the crucible body and heating only its upper part to trigger the evaporation of the material to be evaporated from its free surface, which is the closest to the crucible opening.

Therefore, the quantity of heat received by the crucible body at a point close to the opening, i.e. located at a great distance from the crucible bottom, is higher than the quantity of heat received by a point located at a small distance from the crucible bottom.

Generally, the evaporation device according to the invention allows having, at a given instant of time, a non-constant profile of temperature, along the crucible body.

Moreover, the movability of this first element allows making the time during which a part of the crucible body receives heat from the heating means vary over time. The quantity of heat received over time is thus controlled. This may be advantageously used for example to uncover the crucible body as the evaporation and the reduction of the level of material to be evaporated in the crucible go along.

The crucible according to the invention is particularly adapted to the case of organic materials to be evaporated, entering in the manufacturing of organic light-emitting diodes (OLEDs) for lighting applications or displays (flat screens, mobile devices, etc. . . . ) and for the manufacturing of photovoltaic cells.

Indeed, the organic materials intended to be evaporated from a crucible are in the form of powders, relatively thermally insulating. Therefore, it is required to heat these powders for durations that are sometimes long.

However, the organic materials are sensitive to heat and are degraded when heated: this phenomenon is referred to as pyrolysis. The speed of this pyrolysis is a function of the temperature reached and of the time passed at this temperature. The higher the temperature, the higher the degradation of the material. The quantity of degraded material also increases with the heating duration.

Furthermore, the organic materials used are extremely expensive. It is therefore required to optimize their utilization ratio by minimizing their thermal degradation.

Therefore, the evaporation device according to the invention allows an optimized utilization of material to be evaporated, the latter being heated at a high temperature only when it has to be evaporated.

Moreover, other advantageous and non-limitative characteristics of the evaporation device are:
the first element of the thermal shield is mounted movable in translation with respect to the crucible;
the first element of the thermal shield is mounted movable in rotation with respect to the crucible;
the thermal shield comprises at least one second element, the first element of the thermal shield being movable with respect to this second element, and the first element and the second element being arranged so as to define between each other apertures whose size is adjustable as a function of their position relative to each other;
the evaporation device comprises control means adapted to control at least the first element of the thermal shield to adjust the flow rate of steam of the material to be evaporated through the crucible opening;
the flow rate of steam of the material to be evaporated through the crucible opening is kept constant.

Finally, the invention also relates to a vacuum deposition apparatus including an evaporation device according to the invention.

Embodiments of the invention will be described in detail with reference to the drawings, in which:

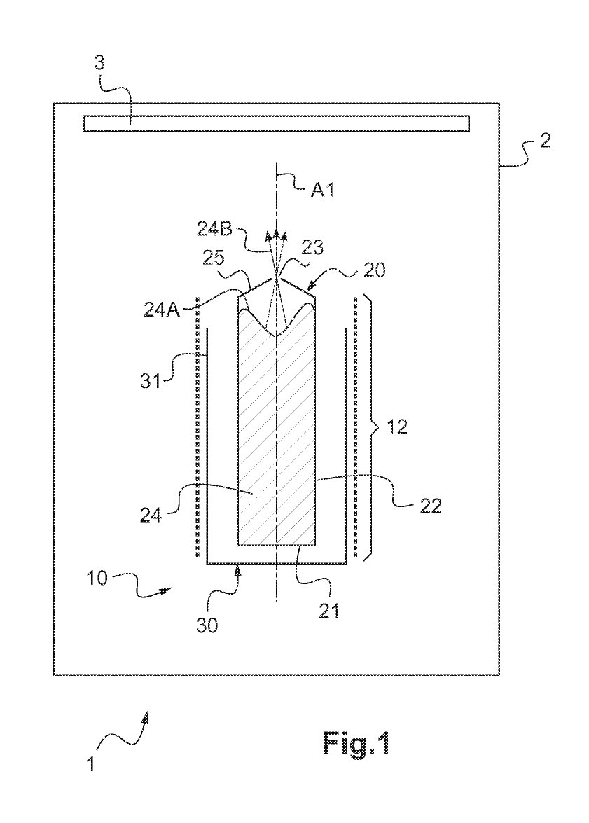

FIG. 1 is a schematic sectional view of a vacuum deposition apparatus equipped with an evaporation device according to a first embodiment of the invention;

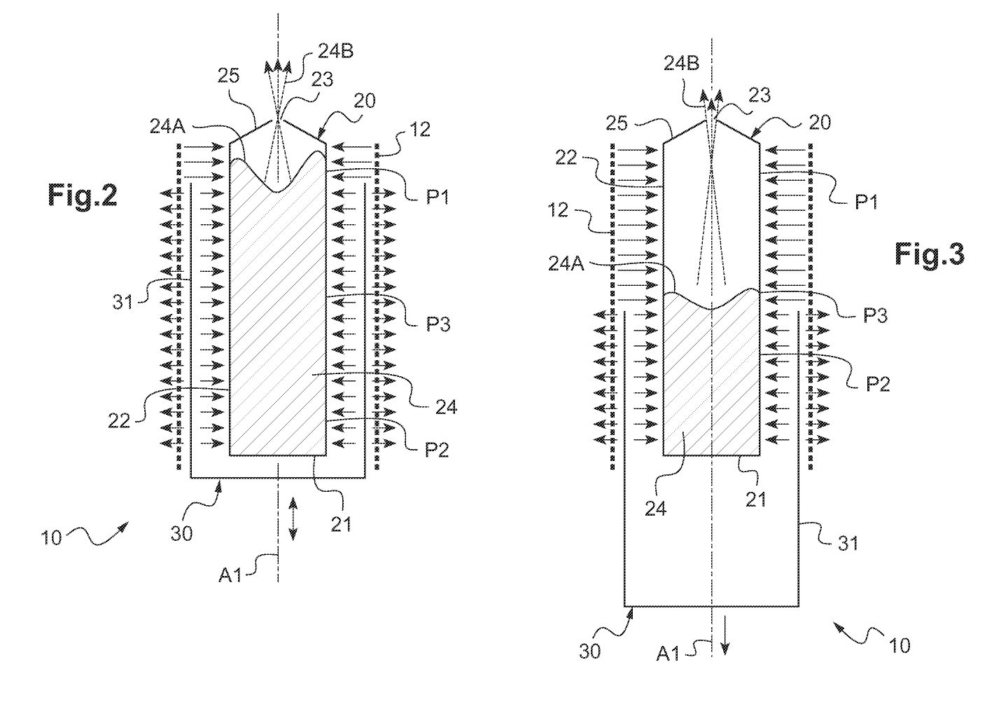

FIG. 2 is a schematic sectional view of an evaporation device including a thermal shield with a first element masking almost entirely the heating means;

FIG. 3 is a schematic sectional view of the evaporation device of FIG. 2, in which the first element has slid along the crucible to uncover the heating means;

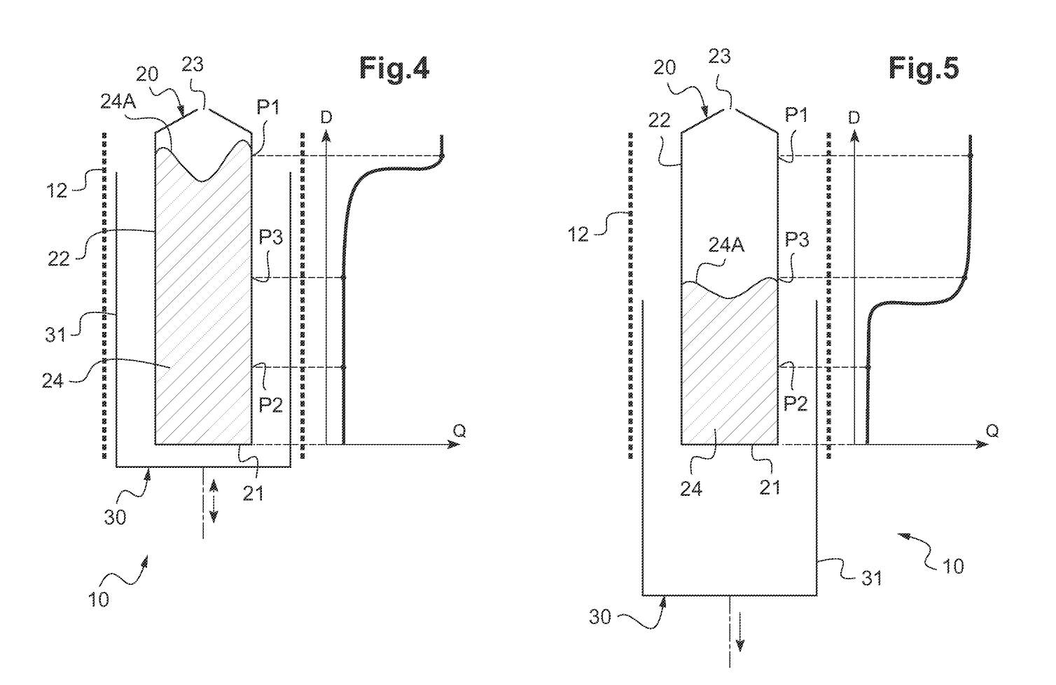

FIG. 4 is a schematic sectional view of a crucible and a thermal shield in which is shown the quantity of heat received by the crucible body when the evaporation device is in the configuration of FIG. 2;

FIG. 5 is a schematic sectional view of a crucible and a thermal shield in which is shown the quantity of heat received by the crucible body when the evaporation device is in the configuration of FIG. 3;

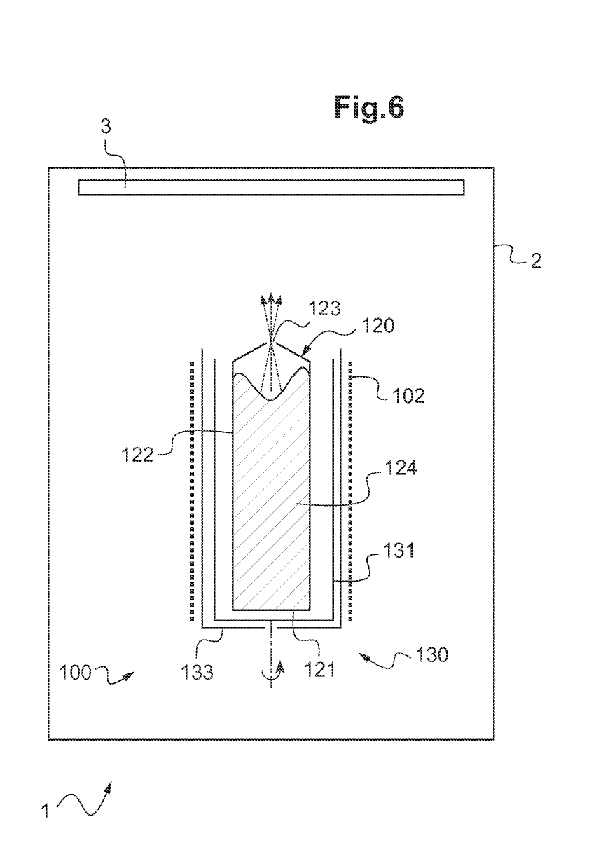

FIG. 6 is a schematic sectional view of a vacuum deposition apparatus equipped with an evaporation device according to the second embodiment of the invention;

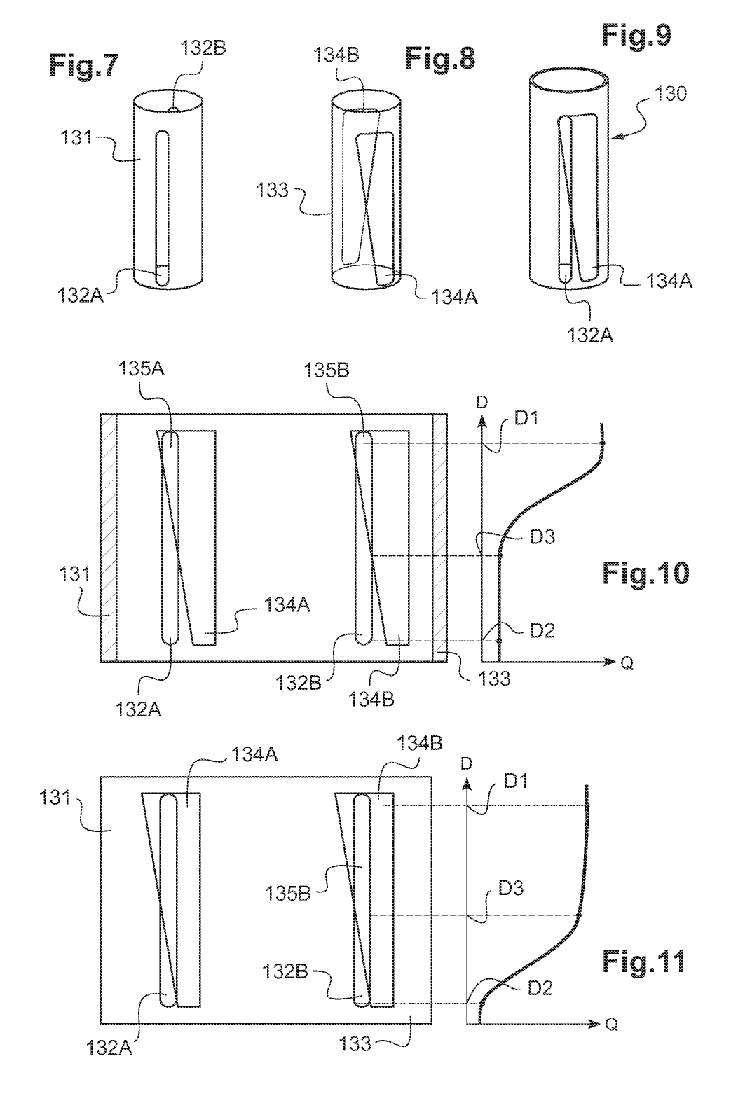

FIG. 7 is a perspective view of a first thermal shield element having vertical slot-shaped apertures according to the second embodiment;

FIG. 8 is a perspective view of a second thermal shield element having trapezoidal apertures according to the second embodiment;

FIG. 9 is a perspective view of the thermal shield according to the second embodiment, comprising the first element of FIG. 7 and the second element of FIG. 8;

FIG. 10 shows the unfolded and flattened view of the thermal shield of FIG. 9 in which is shown the quantity of heat received by the crucible body when the apertures of the first element and the second element are opposite to each other in their upper part;

FIG. 11 shows the unfolded and flattened view of the thermal shield of FIG. 9 in which is shown the quantity of heat received by the crucible body when the apertures of the first element and the second element are opposite to each other over about half their height;

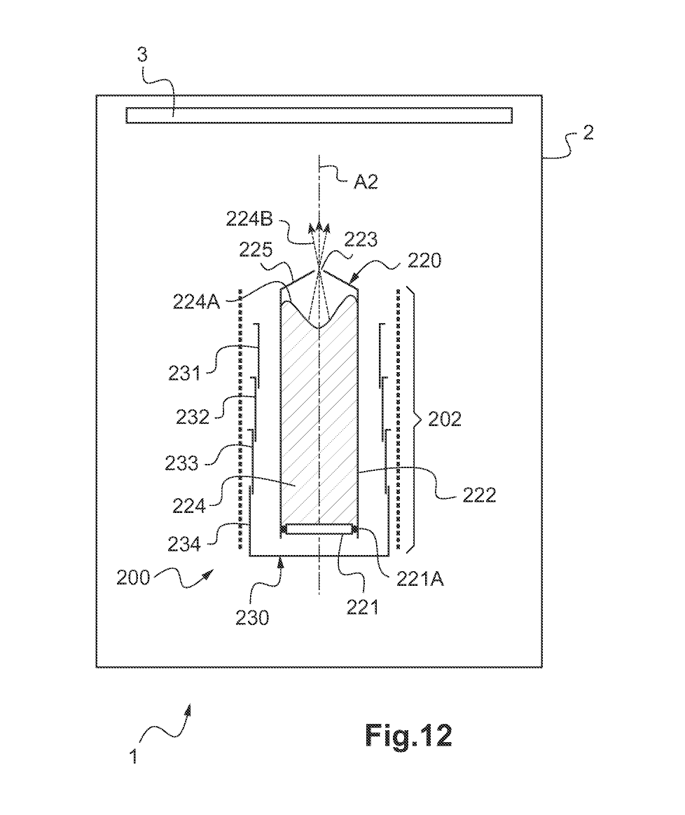

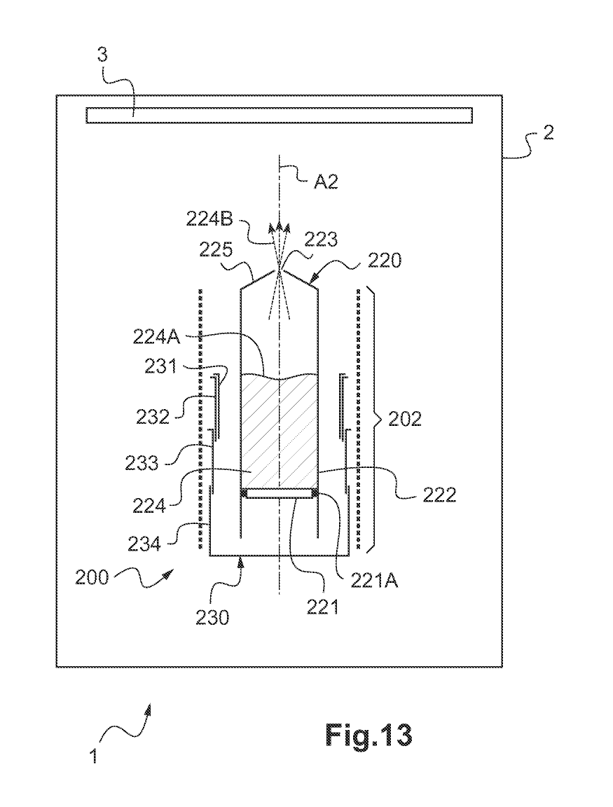

FIGS. 12 and 13 are schematic sectional views of a vacuum deposition apparatus equipped with an evaporation device according to a third embodiment of the invention for two different configurations of the thermal shield.

FIG. 1 shows a schematic sectional view of a vacuum deposition apparatus 1 including an evaporation device 10 according to a first embodiment of the invention.

The vacuum deposition apparatus 1 first includes a vacuum chamber 2 having a substrate 3 in its upper part.

For such a vacuum deposition apparatus 1, the conditions of pressure in the vacuum chamber 2 are such that, in operation, the pressure inside the latter is lower than 10⁻³ millibar (mbar), and preferably lower than 10⁻⁵ mbar. This allows in particular depositing layers on the substrate with a good quality of deposition.

As shown in FIG. 1, the vacuum deposition apparatus 1 also includes an evaporation device 10 placed inside the vacuum chamber 2, generally in the lower part thereof, i.e. below the substrate 3.

The evaporation device 10 first includes a crucible 20 having a substantially cylindrical shape, of revolution about the revolution axis A1. This crucible 20 is delimited, on the one hand, by a bottom 21 in its lower part, and on the other hand, by a body 22 in its lateral part.

The crucible 20 comprises, in its upper part, a neck 25 of truncated shape, extending from the body 22 of the crucible 20 to an opening 23 centered on the revolution axis A1 so that the opening 23 is oriented toward the substrate 3.

The crucible 20 contains a material to be evaporated 24 having a free surface 24A directed toward the opening 23.

The evaporation device 10 also includes heating means 12 arranged at the periphery of the crucible 20 to surround at least partially the body 22 of the crucible 20. The heating means 12 herein extend vertically from the neck 25 of the crucible 20, parallel to the body 22 of the crucible 20, and go down to a level located below the bottom 21 of the crucible 20.

The heating means 12 herein comprise electrical resistances that are heated at a high temperature to transmit heat to the body 22 of the crucible 20 that is opposite thereto.

The conditions of pressure inside the vacuum chamber 2 are such that the heat exchanges between the heating means 12 and the body 22 of the crucible 20 are made essentially through radiation, because the convection exchanges are strongly limited due to the vacuum existing inside the vacuum chamber 2.

The evaporation device 10 also includes a thermal shield 30 located inside the vacuum chamber 2 and interposed between the body 22 of the crucible 20 and the heating means 12.

In a first embodiment of the invention illustrated in FIGS. 2 to 5, this thermal shield 30 herein comprises a single first element 31 of cylindrical shape, whose diameter is greater than the diameter of the body 22 of the crucible 20 in order to surround at least partially the latter but small enough so that the first element 31 may be inserted between the electrical resistances 12 and the body 22 of the crucible 20.

The first element 31 of the thermal shield 30 is herein consisted of a hollow quartz cylinder whose external wall is coated with a layer reflecting the thermal radiation emitted by the heating means 12. This layer may be a metal layer, for example a layer of silver, aluminum, or gold. Thus consisted, the first element 31 of the thermal shield 30 operates as a mirror that reflects a part of the thermal radiation emitted by the heating means 12 and incident on its external surface.

As a variant, the first element could be consisted of a cylinder made of glass or fused silica coated with a layer that is reflective in the infrared. As another variant, the first element could be consisted of a metal cylinder.

In the particular embodiment of the evaporation device 10, shown in FIGS. 2 and 5, the movable part 31 of the thermal shield 30 is mounted movable in translation with respect to the crucible 20 in such a manner that the latter can slide along the body 22 of the crucible 20, between:
an upper position in which the thermal shield 30 covers entirely the body 22 of the crucible 20, i.e. in which the thermal screen 20 masks the body 22 of the crucible 20 with respect to all the heating resistances 12, and
a lower position in which the thermal shield 30 uncovers entirely the body 22 of the crucible 20, i.e. in which the heating resistances 12 are opposite with the body 22 of the crucible 20, the thermal shield 30 being then retracted.

FIGS. 2 to 5 show the thermal shield 30 in intermediate positions between the upper position and the lower position. FIGS. 2 and 4 correspond to a configuration where the first element 31 of the thermal shield 30 has slightly slid along the body 22 of the crucible 20, going down from the upper position so as to uncover the upper part of the heating means 12. FIGS. 3 and 5 correspond to a configuration where the first element 31 of the thermal shield 30 has slid even more along the body 22 of the crucible 20, going down from the position of FIGS. 2 and 4.

Accordingly, according to the position of the movable part 31 of the thermal shield 30 with respect to the crucible 30, it may be distinguished two different cases as a function of the point considered on the body 22 of the crucible 20:

i) Case of point P1: the point P1 is directly opposite the heating means 12, so that the quantity of heat Q received by the body 22 of the crucible 20 at the considered point P1 is high;

ii) Case of point P2: the point P2 is masked with respect to the heating means 12 by the thermal shield 30, and in particular by the first element 31 thereof, so that the quantity of heat Q received by the body 22 of the crucible 20 at the considered point P2 is low.

This can also be seen in FIGS. 4 and 5, in which is represented the quantity of heat Q received by the body 22 of the crucible 20 as a function of the distance D between the considered point and the bottom 21 of the crucible 20, for the two intermediate positions of the first element 31 of the thermal shield 30 with respect to the crucible 20.

It is therefore observed on FIGS. 4 and 5 that the quantity of heat Q received by the body 22 of the crucible 20 at a considered point of this body 22 is conform, at a given instant of time, to a non-constant function of the distance D between the considered point and the bottom 21 of the crucible 20, this function having herein a square shape.

Let's consider now the point P3, as indicated in FIGS. 2 to 5. In the case of FIGS. 2 and 4, the first element 31 of the thermal shield 30 is in such a position with respect to the body 22 of the crucible 20 that the considered point P3 of the body 22 of the crucible 20 is covered by the first element 31 of the thermal shield 30, masking the heating means 12. Hence, as illustrated in FIG. 3, the quantity of heat Q received by the body 22 of the crucible 20 at the point P3 is low.

Likewise, in the case of FIGS. 3 to 5, the first element 31 of the thermal shield 30, having slid a little more downward along the body 22 of the crucible 20, is in such a position with respect to the body 22 of the crucible 20 that the considered point P3 of the body 22 of the crucible 20 is uncovered by the first element 31 of the thermal shield 30, the heating means 12 being then directly opposite the point P3. Hence, as illustrated in FIG. 4, the quantity of heat Q received by the body 22 of the crucible 20 at the point P3 is high.

It is thus understood that the quantity of heat Q received by the body 22 of the crucible 20 is adjustable as regards the movement, herein the sliding, of the first element 31 of the thermal shield 30 with respect to the crucible 20.

Let's consider now the material to be evaporated 24, contained in the crucible 20 and in particular its free surface 24A directed toward the opening 23 of the crucible 20.

In the configuration of FIGS. 2 and 4, the free surface 24A is at the same level than the point P1, i.e. at a great distance D from the bottom 21 of the crucible 20, and the body 22 of the crucible 20 receives at this level a high quantity of head Q from the heating means 12, due to the fact that the first element 31 of the thermal shield 30 does not mask these latter.

On the other hand, for the parts of the material to be evaporated 24 located at a smaller distance D from the bottom 21 of the crucible 20 than the free surface 24A, the quantity of heat Q received by the body 22 of the crucible 20 is lower, the latter being non-uniform as a function of the distance D from the bottom 21 of the crucible 20, as can be seen in FIG. 3.

Hence, the free surface 24A of the material to be evaporated 24 is strongly heated, whereas the parts of the material to be evaporated 24 located close to the bottom 21 of the crucible 20 are slightly heated.

Consequently, the temperature of the material to be evaporated 24 is increased enough at its free surface 24A so that a flow of steam 24B is generated from this free surface 24A and escapes through the opening 23 of the crucible 20.

Likewise, the temperature of the material to be evaporated 24 at the middle or at the bottom of the crucible 20 is increased but the temperature rising is limited, because the quantity of heat Q received by the body 22 of the crucible 20 at these parts is low enough so that the temperature reached generates no deterioration of the material to be evaporated 24.

A flow of steam 24B being generated from the free surface 24A, the material to be evaporated 24 contained in the crucible 20 is consumed by evaporation so that the level of the free surface 24A comes down in the body 22 of the crucible 20.

This may be illustrated by FIGS. 3 and 5, where the level of the free surface 24A has come down and moved closer to the bottom 21 of the crucible 20. Likewise, as described above, the first element 31 of the thermal shield 30 has slid downward along the body 22 of the crucible 20 from its initial position, represented in FIGS. 2 and 4.

The free surface 24A is now at the same level as the point P3 on the body 22 of the crucible 20 and the body 22 of the crucible 20 receives at this level a high quantity of heat Q from the heating means 12, due to the fact that the first element 31 does not mask these latter.

It is indeed observed in FIG. 4 that the quantity of heat Q received by the body 22 of the crucible 20 has a non-uniform profile as a function of the distance D from the bottom 21 of the crucible 20, this profile having varied with respect to the profile represented in FIG. 3 after the movement in translation of the first element 31 of the thermal shield 30 parallel to the revolution axis A1.

Hence, as explained hereinabove, the temperature of the material to be evaporated 24 is increased enough at its free surface 24A so that a flow of steam 24B is generated and directed toward the opening 23 of the crucible 20.

It is therefore understood that it is possible, with the above-described evaporation device 10, to adjust the quantity of heat Q received by the body 22 of the crucible 20 thanks to the movement of the first element 31 of the thermal shield 30 with respect to the crucible 20.

It is in particular possible to control the position of the first element 31 of the thermal shield 30 with respect to the crucible 20 over time and, as the level of the material to be evaporated 24 goes down in the crucible 20, so as to adapt the profile of the quantity of heat Q received by the body 22 of the crucible 20 to the distribution of the material to be evaporated 24 in the crucible.

That way, the free surface 24A may be heated enough all along the evaporation of the material to be evaporated 24 so as to keep the flow of steam 24B through the opening 23 of the crucible 20.

Advantageously, in another embodiment of the evaporation device, it is therefore provided that control means controlling at least the first element of the thermal shield to adjust the flow rate of steam of the material to be evaporated through the crucible opening. These control means allow for example activating the moving part of the thermal shield to make the latter slide along the crucible body, so that the flow rate of steam of the material to be evaporated through the crucible opening is constant.

FIGS. 6 to 10 relates to a second embodiment of the invention,

Hence, it is shown in FIG. 6 the vacuum deposition apparatus 1 with the vacuum chamber 2 and the substrate 3.

In this second embodiment, an evaporation device 100 is placed inside the vacuum chamber 2 of the vacuum deposition apparatus 1. The evaporation device 100 includes:
a crucible 120, similar to that of the first embodiment, containing a material to be evaporated 124 and comprising a bottom 121, a body 122 and an opening 123, and
heating means 102, similar to those of the first embodiment, surrounding at least partially the body 122 of the crucible 120.

The evaporation device 100 further includes a thermal shield 130, comprising:
a first element 131 that is movable with respect to the crucible 120, and
a second element 133 with respect to which the first element 131 is also movable.

FIGS. 7 to 9 detail the characteristics of the thermal shield 130, as well as the first and second elements 131, 133.

Hence, it is shown in FIG. 7 the first element 131 which has the shape of a cylinder of revolution, herein consisted of a metal sheet.

As a variant, the first element could be, for example, formed of a quartz cylinder of revolution comprising a metal deposit or any other material able to play the role of a thermal shield.

The first element 131 comprises two identical first openings 132A, 132B, which are herein diametrically opposed to each other. The first openings 132A, 132B are in the form of vertical slots extending between the lower part and the upper part of the first element 131. Thus formed, the total surface of the first openings 132A, 132B correspond to about 50% of the surface of the first element 131.

Likewise, it is shown in FIG. 8 a second element 133 which has the shape of a cylinder of revolution, also consisted of a metal sheet.

As another variant, the second element could be for example formed of a quartz cylinder of revolution comprising a metal deposit or any other material able to play the role of a thermal shield.

This second element 133 also comprises two identical second openings 134A, 134B, which are diametrically opposed to each other. These second openings 134A, 134B have a trapezoidal shape and extend between the lower part and the upper part of the second element 132, the second openings 134A, 134B being wider in the upper part than in the lower part.

The height of the second openings 124A, 134B is herein substantially equal to the height of the first openings 132A, 132B. Likewise, the first openings 132A, 132B have a width substantially equal to the width of the second openings 134A, 134B taken at the bases thereof.

FIG. 9 shows the thermal shield 130 of this second embodiment, including the first element 131 of FIG. 7 and the second element 133 of FIG. 8.

In particular, the diameter of the second element 133 is herein greater than the diameter of the first element 131, so that the second element 133 surrounds entirely the first element 131. As shown in FIG. 6, the first element 131 is arranged at the periphery of the crucible 120, opposite the body 122 of the crucible 120, to cover it entirely. Moreover, the second element 133 is inserted between the first element 131 and the heating means 102 of the evaporation device 100.

Thus consisted, the thermal shield 130 is interposed between the body 122 of the crucible 120 and the heating means 102.

As an alternative, the diameter of the second element may be smaller than the diameter of the first element, so that the first element surrounds entirely the second element.

In this second embodiment, the first element 131, which is movable with respect to the crucible 120, is also movable, herein in rotation, with respect to the second element 133.

As a function of the position of the first openings 132A, 132B with respect to the position of the second openings 134A, 134B, these latter are partially or totally opposite relative to each other.

Hence, the first element 131 and the second element 132 define between each other apertures whose size is adjustable as a function of their relative positions.

By rotation of the first element 131 with respect to the second element 133, it is indeed possible to bring the first openings 132A, 132B opposite the second openings 134A, 134B.

The first openings 132A, 132B, on the one hand, and the second openings 134A, 134B, on the other hand, being herein diametrically opposed to each other, it is understood that, for example, when the first opening 132A is opposite the second opening 134A, then the first opening 1328 is opposite the second opening 1348.

Moreover, the shape of the second openings 134A, 134B being trapezoidal, the height of the apertures formed by the arrangement of the first element 131 with respect to the second element 133 also varies as a function of their relative positions and may be adjusted by rotation of the first element 131 with respect to the second element 133.

It will be understood that a thermal shield 130 having apertures and interposed between the heating means 102 and the body 122 of the crucible 120 of the evaporation device 100 transmits almost integrally the heat radiated by the heating means 102 toward the body 122 of the crucible 120.

This is illustrated in FIGS. 10 and 11 in which is shown:
on the left of the figure, an unfolded and flattened view of the thermal shield 130, making appear the superimposition of the first element 131 with the second element 133, and
on the right of the figure, the quantity of heat Q received at a considered point of the body 122 of the crucible 120 as a function of the distance D of this point from the bottom 121 of the crucible.

FIG. 10 corresponds to a case where the first openings 132A, 1328 of the first element 131 are partially opposite the second openings 134A, 134B of the second element 133 of the thermal shield 130 of FIG. 9.

In the configuration of FIG. 10, it is observed that the apertures 135A, 135B defined by the arrangement of the first element 131 with respect to the second element 133 have an almost-trapezoidal shape, and a height substantially equal to half the height of the first openings 132A, 1328.

As shown on the right curve of FIG. 10, it is thus understood that the quantity of heat Q received at a distance D1 from the bottom 121 of the crucible 120 is high, whereas the quantity of heat Q received at a distance D3 from the bottom 121 of the crucible 120 is low, and the quantity of heat Q received at a distance D2 from the bottom 121 of the crucible 120 is very low, as there exists no aperture for this distance D2.

Hence, it is observed that the quantity of heat Q received by the body 122 of the crucible 120 at a considered point of this body 122 is conform, at a given instant of time, to a non-constant function of the distance D between this considered point and the bottom 121 of the crucible 120.

From the situation described in FIG. 10, the relative positions of the first element 131 and the second element 133 are varied, by rotation of the first element 131, to bring the first openings 132A, 1328 almost totally opposite the second openings 134A, 1348. There thus results the situation described in FIG. 11.

In this configuration, it is then observed that the sizes of the apertures 135A, 135B defined between the first element 131 and the second element 133 have changed, these latter being now greater than those of the preceding situation of FIG. 10, extending over almost all the height of the first openings 132A, 1328.

As shown in the right curve on FIG. 11, it is thus understood that not only the quantity of heat Q received at a distance D1 from the bottom 121 of the crucible 120 but also the quantity of heat Q received at a distance D3 from the bottom 121 of the crucible 120 is high. On the other hand, the quantity of heat Q received at a distance D2 from the bottom 121 of the crucible 120 is always comparatively lower, as there exists no aperture for this distance D2.

Hence, it is observed that the quantity of heat Q received by the body 122 of the crucible 120 at a considered point of this body 122 is adjustable thanks to the rotation of the first element 131 of the thermal shield 130 with respect to the crucible 120.

Advantageously, it may also be contemplated that the thermal shield 130 taken as a whole, i.e. the first element 131 and the second element 133, are in rotation with respect to the crucible 120, so that the material to be evaporated 124 contained in the crucible 120 is heated uniformly over all the periphery of the crucible 120.

As a variant, the first and second elements could include a plurality of openings, whose shape and position could be adapted to the profile of temperature desired on the crucible body.

FIGS. 12 and 13 relates to a third embodiment of the invention.

Hence, it is shown in FIGS. 12 and 13 the vacuum deposition apparatus 1 with the vacuum chamber 2 and the substrate 3.

In this third embodiment, an evaporation device 200 is placed inside the vacuum chamber 2 of the vacuum deposition apparatus 1. The evaporation device 200 includes (see for example FIG. 12) a crucible 220, identical to that of the first embodiment, containing a material to be evaporated 24 and comprising a bottom 221, a body 222 and an opening 223.

Preferably, the bottom 221 of the crucible 220 is herein mounted movable in translation with respect to the crucible 220, along a longitudinal direction of the crucible 220, i.e. the direction of the axis A2. An O-ring seal 221A, for example made of rubber, arranged on the periphery of the movable bottom 221, provides the tightness between the bottom 221 and the body 222 of the crucible 220.

In this configuration, the evaporation device 200 also comprises additional control means (not shown) that control the translation of the bottom 221 of the crucible 220.

In other words, these control means operate the bottom 221 of the crucible 220 to move the later along the crucible body 222.

Such control means may include for example an operating rod connected, on one side, to a motor, and on the other side, to the bottom 221 of the crucible 220, the translational movement of the operating rod being then transmitted to the bottom 221 of the crucible 220.

Thanks to the O-ring seal 221A, the bottom 221 of the crucible 220 may then slid tightly along the body 222 of the crucible 220.

The evaporation device 220 also includes heating means 102, identical to those of the first embodiment, surrounding at least partially the body 222 of the crucible 220.

The evaporation device 220 further includes a thermal shield 230 herein comprising (see FIGS. 12 and 13):
a first element 231 that is movable with respect to the crucible 220, and
a second element 232, a third element 233, and a fourth element 234 with respect to which the first element 131 is also movable.

As shown in FIGS. 12 and 13, this thermal shield 230 is of the “telescopic” type, with first, second, third and fourth elements 231, 232, 233, 234, whose external diameter is adjusted so that the first element 231 nests into the second element 232, the second element 232 nests into the third element 233 nests into the fourth element 234.

That way, the height of the thermal shield 230, i.e. its size along the revolution axis A1 (see FIGS. 12 and 13), may be roughly adjusted.

Therefore, FIG. 12 shows the thermal shield 230 according to its longest height when all the elements 231, 232, 233, 234 are unfolded. FIG. 13 shows the thermal shield 230 when the first element 231 has been moved downward, nested into the second element 232, thus uncovering the heating means 12 of the evaporation device 200.

It is thus understood that the quantity of heat Q received by the body 222 of the crucible 220 at a considered point of this body 22 is conform, at a given instant of time, to a non-constant function of the distance D between the considered point and the bottom 221 of the crucible 220, such function being adjustable as regards the displacement of the first element 231 of the thermal shield 230 with respect to the crucible 220.

The material to be evaporated 24 being subjected to the radiation of the heating means 12, a flow of steam 24B is established through the opening 223 of the crucible 220, so that the free surface 24A of the material to be evaporated 24 comes down in the crucible 220 (see FIG. 13) to a level located herein opposite the first element 231.

Thanks to the additional control means that operate the bottom 221 of the crucible 220, it is possible to adjust precisely the position of the free surface 24A in the body 222 of the crucible 220 and hence the quantity of heat received by the material to be evaporated 24, in particular at the free surface 24A thereof.

That way, the flow rate of the material to be evaporated 24 through the opening 223 of the crucible 220 may be finely adjusted, thanks to the displacement of the bottom 221 of the crucible 220.

It will however be noted that, even if the third embodiment of the evaporation device 200 shown in FIGS. 12 and 13 combines a thermal shield 230 of telescopic type with a crucible 220, whose bottom 221 is movable, these latter can be used separately from each other within another evaporation device according to the invention.

1. An evaporation device (10) for a vacuum deposition apparatus (1) including:
a crucible (20) intended to contain a material to be evaporated (24) and comprising a bottom (21), a body (22) and an opening (23), and
heating means (12) surrounding at least partially the body (22) of the crucible (20),
the evaporation device (10) being intended to be placed inside a vacuum chamber (2) of the vacuum deposition apparatus (1) in which the pressure is lower than 10⁻³ mbar, and being characterized in that it also includes at least one thermal shield (30) interposed between the body (22) of the crucible (20) and the heating means (12), the thermal shield (30) comprising at least one element (31) that is movable with respect to the crucible (20) and that is designed in such a manner that the quantity of heat (Q) received by the body (22) of the crucible (20) at a considered point of this body (22) is conform, at a given instant of time, to a non-constant function of the distance (D) between the considered point and the bottom (21) of the crucible (20), this function being adjustable as regards at least one degree of movability of the first element (31) of the thermal shield (30) with respect to the crucible (20).

2. The evaporation device (10) according to claim 1, wherein the first element (31) of the thermal shield (30) is mounted movable in translation with respect to the crucible (20).

3. The evaporation device (10) according to claim 1, wherein the first element (31) of the thermal shield (30) is mounted movable in rotation with respect to the crucible (20).

4. The evaporation device (100) according to claim 1, wherein the thermal shield (130) comprises at least one second element (133), the first element (131) of the thermal shield (130) being movable with respect to this second element (133), and the first element (131) and the second (133) being arranged so as to define between each other apertures (135A, 135B) whose size is adjustable as a function of their relative positions.

5. The evaporation device (10; 100) according to claim 1, comprising control means adapted to control at least the first element (31; 131) of the thermal shield (30; 130) to adjust the flow rate of steam of the material to be evaporated (24; 124) through the opening (23; 123) of the crucible (20; 120).

6. The evaporation device (10; 100) according to claim 5, wherein the flow rate of steam of the material to be evaporated (24; 124) through the opening (23; 123) of the crucible (20; 120) is kept constant.

7. The evaporation device (200) according to claim 1, wherein the bottom (221) of the crucible (220) is mounted movable in translation with respect to the body (222) of the crucible (220).

8. The evaporation device (200) according claim 7, comprising additional control means adapted to control the bottom (221) of the crucible (220) to adjust the flow rate of the material to be evaporated (224) through the opening (223) of the crucible (220).

9. A vacuum deposition apparatus (1) comprising an evaporation device (10; 100; 200) according to claim 1.

10. The evaporation device (10) according to claim 2, wherein the first element (31) of the thermal shield (30) is mounted movable in rotation with respect to the crucible (20).

11. The evaporation device (100) according to claim 2, wherein the thermal shield (130) comprises at least one second element (133), the first element (131) of the thermal shield (130) being movable with respect to this second element (133), and the first element (131) and the second (133) being arranged so as to define between each other apertures (135A, 135B) whose size is adjustable as a function of their relative positions.

12. The evaporation device (100) according to claim 3, wherein the thermal shield (130) comprises at least one second element (133), the first element (131) of the thermal shield (130) being movable with respect to this second element (133), and the first element (131) and the second (133) being arranged so as to define between each other apertures (135A, 135B) whose size is adjustable as a function of their relative positions.

13. The evaporation device (10; 100) according to claim 2, comprising control means adapted to control at least the first element (31; 131) of the thermal shield (30; 130) to adjust the flow rate of steam of the material to be evaporated (24; 124) through the opening (23; 123) of the crucible (20; 120).

14. The evaporation device (10; 100) according to claim 3, comprising control means adapted to control at least the first element (31; 131) of the thermal shield (30; 130) to adjust the flow rate of steam of the material to be evaporated (24; 124) through the opening (23; 123) of the crucible (20; 120).

15. The evaporation device (10; 100) according to claim 4, comprising control means adapted to control at least the first element (31; 131) of the thermal shield (30; 130) to adjust the flow rate of steam of the material to be evaporated (24; 124) through the opening (23; 123) of the crucible (20; 120).

16. The evaporation device (200) according to claim 2, wherein the bottom (221) of the crucible (220) is mounted movable in translation with respect to the body (222) of the crucible (220).

17. The evaporation device (200) according to claim 3, wherein the bottom (221) of the crucible (220) is mounted movable in translation with respect to the body (222) of the crucible (220).

18. The evaporation device (200) according to claim 4, wherein the bottom (221) of the crucible (220) is mounted movable in translation with respect to the body (222) of the crucible (220).

19. The evaporation device (200) according to claim 5, wherein the bottom (221) of the crucible (220) is mounted movable in translation with respect to the body (222) of the crucible (220).

20. The evaporation device (200) according to claim 6, wherein the bottom (221) of the crucible (220) is mounted movable in translation with respect to the body (222) of the crucible (220).
